(19) United States
(12) Patent Application Publication
(10) Pub. No.: US 2026/0209551 A1
(43) Pub. Date: Jul. 23, 2026

(54) SLURRY COMPOSITION AND METHOD OF MANUFACTURING INTEGRATED CIRCUIT DEVICE USING THE SAME

(71) Applicant: SAMSUNG ELECTRONICS CO., LTD., Suwon-si (KR)

(72) Inventors: Soobum Kim, Suwon-si (KR); Ungyu Paik, Seoul (KR); Gayoung Kim, Suwon-si (KR); Sangkyun Kim, Suwon-si (KR); Sanghyun Park, Suwon-si (KR); Taeseup Song, Seoul (KR); Ganggyu Lee, Seoul (KR); Junsang Lee, Suwon-si (KR)

(73) Assignees: SAMSUNG ELECTRONICS CO., LTD., Suwon-si (KR); IUCF-HYU (INDUSTRY-UNIVERSITY COOPERATION FOUNDATION HANYANG UNIVERSITY), Seoul (KR)

(21) Appl. No.: 19/335,650

(22) Filed: Sep. 22, 2025

(30) Foreign Application Priority Data
Jan. 21, 2025 (KR) 10-2025-0008851

(51) Int. Cl. C09G 1/02; H01L 21/321

(52) U.S. Cl. CPC C09G 1/02; H10P 52/403

(57) ABSTRACT

Provided is a slurry composition used for polishing a target structure including a film to be polished and a film not to be polished, the slurry composition including polishing particles, an inhibitor including a chalcogen group, and an oxidizing agent, wherein the inhibitor reacts with the oxidizing agent to form a dichalcogenide bond and be adsorbed onto the film not to be polished.

### CROSS-REFERENCE TO RELATED APPLICATION

This application is based on and claims priority under 35 U.S.C. § 119 to Korean Patent Application No. 10-2025-0008851, filed on Jan. 21, 2025, in the Korean Intellectual Property Office, the disclosure of which is incorporated by reference herein in its entirety.

### BACKGROUND

The present disclosure relates to a slurry composition and a method of manufacturing an integrated circuit device using the same, and more particularly, to a slurry composition for polishing a polishing target film by using a chemical mechanical polishing (CMP) process, and a method of manufacturing an integrated circuit device using the same.

Due to the development of electronic technology, down-scaling of integrated circuit devices is rapidly progressing, and line widths and pitches of unit devices included in integrated circuit devices are also becoming smaller. Accordingly, it is necessary to selectively increase the polishing rate of a film being polished, such as a metal film, and selectively decrease the polishing rate of a film that is not to be polished, such as an insulating film.

### SUMMARY

The problem to be solved by the technical idea of the present disclosure is to provide a slurry composition that selectively polishes a polishing target film in a target structure by using a slurry composition including polishing particles, a compound including a chalcogen group, an oxidizing agent, and a nonionic compound.

According to an aspect of the present disclosure, there is provided a slurry composition used for polishing a target structure including a polishing target film and a non-polishing target film, the slurry composition including polishing particles, an inhibitor including a chalcogen group; and an oxidizing agent, wherein the inhibitor reacts with the oxidizing agent to form a dichalcogenation bond and is adsorbed onto the non-polishing target film.

According to an aspect of the present disclosure, there is provided a method of manufacturing an integrated circuit device, the method comprising forming a target structure including a polishing target film and a non-polishing target film on a substrate, and polishing the target structure by applying a slurry composition onto the target structure, wherein the slurry composition includes polishing particles, an oxidizing agent, and an inhibitor including a chalcogen group and reacting with the oxidizing agent to form a dichalcogenation bond and being adsorbed onto the non-polishing target film.

In the above method, the inhibitor including a chalcogen group includes cysteine, the oxidizing agent includes hydrogen peroxide, and the cysteine reacts with the hydrogen peroxide to form cystine including a disulfide bond.

In the above method, the film to be polished includes molybdenum (Mo), and the film not to be polished includes silicon nitride, silicon oxide, or a combination thereof.

In the above method, in the polishing of the target structure, the cystine is selectively adsorbed onto a surface of the film not to be polished in the target structure.

In the above method, in the polishing of the target structure, a polishing rate of the film to be polished is greater than a polishing rate of the film not to be polished.

In the above method, the slurry composition further includes a nonionic compound including a hydrophilic functional group.

In the above method, the nonionic compound includes sorbitol, 1,3-propanediol, N,N-dimethyl acetamide, or a combination thereof.

In the above method, a content of the inhibitor is in a range from about 0.001 wt % to about 10 wt %, based on the total weight of the slurry composition, and a content of the nonionic compound is in a range from about 0.001 wt % to about 10 wt %, based on the total weight of the slurry composition.

In the above method, the polishing of the target structure includes controlling pH of the slurry composition to a range of 2 to 9.

According to an aspect of the present disclosure, there is provided a slurry composition used for polishing a target structure including a polishing target film including molybdenum (Mo) and a non-polishing target film including silicon nitride, silicon oxide, or a combination thereof, the slurry composition including polishing particles, an oxidizing agent, an inhibitor including cysteine, and a nonionic compound including a hydrophilic functional group, wherein the cysteine reacts with the oxidizing agent to form cystine including a disulfide bond, and the cystine selectively adsorbs to a surface of the non-polishing target film in the target structure.

### BRIEF DESCRIPTION OF DRAWINGS

Embodiments will be more clearly understood from the following detailed description taken in conjunction with the accompanying drawings in which:

FIG. 1 is a partial cutaway perspective view schematically illustrating part of a polishing device according to embodiments;

FIG. 2 is a flowchart for explaining a polishing process according to embodiments;

FIG. 3 and FIG. 4 are cross-sectional views for explaining a process sequence of a method of manufacturing an integrated circuit device according to embodiments;

FIG. 5A and FIG. 5B are graphs showing the results of a polishing process using a slurry composition according to embodiments;

FIG. 6 is a graph showing the results of a polishing process using a slurry composition according to embodiments;

FIG. 7A to FIG. 7C are graphs showing results of a polishing process using a slurry composition according to embodiments; and

FIG. 8 is a graph showing results of a polishing process using a slurry composition according to embodiments.

### DETAILED DESCRIPTION OF EMBODIMENTS

Hereinafter, embodiments of the technical idea of the present disclosure will be described in detail with reference to the accompanied drawings. Like reference numerals are used for like elements in the drawings, and overlapping descriptions thereof are omitted.

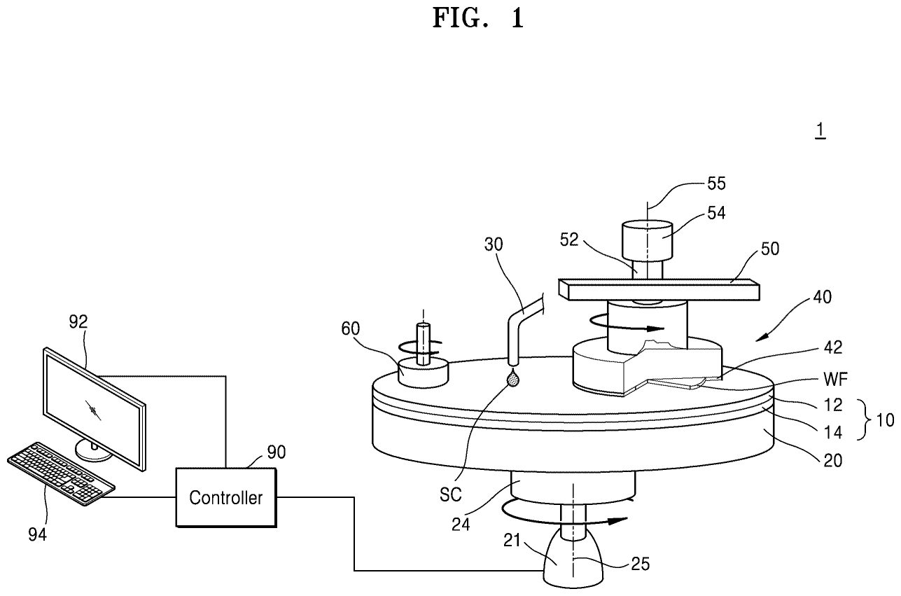

FIG. 1 is a partial cutaway perspective view schematically illustrating a part of a polishing device 1 according to embodiments.

Referring to FIG. 1, the polishing device 1 may be used to polish a surface of a wafer WF using a chemical mechanical polishing (CMP) process. FIG. 1 illustrates a rotary polishing device 1.

The polishing device 1 may include a platen 20 in the shape of a rotary disk. The platen 20 may be arranged to be rotatable around a central axis 25 of the platen 20 using a motor 21. For example, the motor 21 may rotate a drive shaft 24 to rotate the platen 20. A polishing pad 10 may be placed on an upper surface of the platen 20. The polishing pad 10 may include a polishing layer 12 and a support layer 14. The support layer 14 may serve to support the polishing pad 10 so that the polishing pad 10 may be attached to the platen 20.

A polishing target film, such as a metal-including film or an insulating film, may be formed on the wafer WF. The wafer WF may be formed as a structure including various substrates, such as a structure for forming an integrated circuit element, a structure for forming a Thin Film Transistor-Liquid Crystal Display (TFT-LCD), a glass substrate, a ceramic substrate, and a polymer substrate.

The polishing device 1 may include a slurry port 30 for supplying a slurry composition SC according to embodiments onto the polishing pad 10. The polishing device 1 may further include a polishing pad conditioner 60. The polishing pad conditioner 60 may be configured to perform a dressing process for periodically polishing and flattening a surface of the polishing pad 10 so that the polishing pad 10 may provide a constant polishing efficiency.

The polishing device 1 may include at least one carrier head 40. A wafer WF may be loaded onto the carrier head 40. The carrier head 40 may be configured to rotate while pressing the wafer WF toward the platen 20 in a state that the wafer WF loaded onto the carrier head 40 is positioned to face the platen 20. In FIG. 1, only one carrier head 40 is illustrated on the polishing pad 10, but a plurality of carrier heads 40 may be placed on the polishing pad 10. The carrier head 40 may be configured to control the pressure applied to the wafer WF.

The carrier head 40 may include a retaining ring 42 necessary to hold the wafer WF. The carrier head 40 is supported by a support structure 50, for example, a carousel or a track, and is connected to a carrier head rotation motor 54 via a drive shaft 52 so as to rotate around a central axis 55 of the drive shaft 52.

The polishing device 1 may further include a controller for controlling the rotation of the platen 20. The controller may include a controller 90 such as a general-purpose programmable digital computer, an output device 92 such as a monitor, and an input device 94 such as a keyboard. In FIG. 1, the controller is shown as being connected only to the motor 21, but this is only an example, and the controller may also be connected to the carrier head 40 to control the pressure or rotation speed of the carrier head 40. In addition, the controller may be connected to the slurry port 30 to control the supply of the slurry composition SC.

In example embodiments, the slurry composition SC may be used to polish a polishing target film on the wafer WF. The slurry composition SC according to the embodiment may include abrasive particles, an inhibitor including a chalcogenide group, an oxidizing agent, and a nonionic compound including a hydrophilic functional group.

In example embodiments, the slurry composition SC may be a chemical mechanical polishing slurry composition used for chemical mechanical polishing of a metal film. At this time, the metal film that is chemically and mechanically polished using the slurry composition SC may include Mo, W, or a combination thereof.

In example embodiments, the abrasive particles may be at least one selected from the group consisting of silica, alumina, ceria, titania, zirconia, magnesia, germania, and mangania. For example, the abrasive particles may be silica.

In example embodiments, the content of the abrasive particles may be in a range from about 0.01 wt % to about 20 wt % based on the total amount of the slurry composition SC. For example, the content of the abrasive particles may be in a range from about 0.01 wt % to about 20 wt %, from about 0.01 wt % to about 10 wt %, from about 0.1 wt % to about 20 wt %, or from about 0.1 wt % to about 10 wt %, based on the total amount of the slurry composition SC, but the present disclosure is not limited thereto. For purposes of the present disclosure, the term “about” means ±5%.

In example embodiments, the inhibitor may be a compound including a chalcogen group. The inhibitor may react with the oxidizing agent to form a dichalcogenide bond. The compound including the chalcogen group may refer to a compound including a chalcogen element. For example, the compound including the chalcogen group may include sulfur(S), selenium (Se), tellurium (Te), or a combination thereof, but the present disclosure is not limited thereto.

For example, the chalcogen group may include cysteine, and the oxidizing agent may include hydrogen peroxide (H₂O₂), but the present disclosure is not limited thereto. As shown in Reaction 1, cysteine may combine with hydrogen peroxide to form cystine. Cystine may include a disulfide bond.

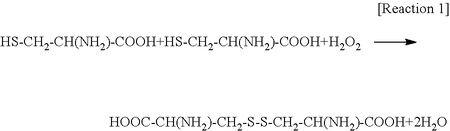

In example embodiments, the cystine may be selectively adsorbed on a surface of the non-polishing target film in a target structure including a polishing target film and a non-polishing target film. At this time, the polishing target film may be a metal film, and the non-polishing target film may be an insulating film. For example, the polishing target film may be a metal film including molybdenum, and the non-polishing target film may include silicon nitride (Si₃N₄), silicon oxide (SiO₂), or a combination thereof.

In example embodiments, due to the hydrophilic nature of the cystine, the cystine may have low affinity with molybdenum (Mo). On the other hand, a hydrogen bond may be formed between the disulfide bond of the cystine and the silicon nitride and silicon oxide. Therefore, the cystine is not adsorbed on the polishing target film including molybdenum, but may be selectively adsorbed on the surface of the non-polishing target film including silicon nitride and/or silicon oxide.

In example embodiments, when the slurry composition SC includes cystine rather than cysteine as an inhibitor, the cystine and the polishing particles (e.g., silica) may be aggregated by hydrogen bonding. In this case, the dispersibility of the polishing particles may be reduced, and the polishing rate using the slurry composition SC may be reduced.

In example embodiments, the content of the inhibitor including the chalcogen group may be in a range from about 0.001 wt % to about 10 wt % based on the total amount of the slurry composition SC. The content of the oxidizing agent may be in a range from about 0.0001 wt % to about 10 wt % based on the total amount of the slurry composition SC.

In example embodiments, the nonionic compound including a hydrophilic functional group may include sorbitol, 1,3-propanediol, N,N-dimethyl acetamide, or a combination thereof. The nonionic compound including a hydrophilic functional group may include glycerol, ethylene glycol, propylene glycol, diethylene glycol, triethylene glycol, xylitol, 2,2-dimethyl-1,3 propanediol, 2-methyl-1,3-propanediol, methanamide, and ethanamide, or a combination thereof.

In example embodiments, the content of the nonionic compound including the hydrophilic functional group may be in a range from about 0.001 wt % to about 10 wt % based on the total amount of the slurry composition SC.

In example embodiments, a nonionic compound including a hydrophilic functional group may be combined with the cystine and selectively adsorbed onto a surface of the non-polishing target film. Due to the hydrophilic nature of the cystine, the cystine and the nonionic compound including the hydrophilic functional group may be combined. Because a complex formed by combining the cystine and the nonionic compound including the hydrophilic functional group is selectively adsorbed onto the surface of the non-polishing target film, the frictional force of the non-polishing target film may be reduced, thereby suppressing the polishing rate of the non-polishing target film.

In example embodiments, the slurry composition may further include a pH controller. The pH controller may be at least one selected from the group consisting of, for example, lithium hydroxide, sodium hydroxide, potassium hydroxide, cesium hydroxide, sulfuric acid, nitric acid, hydrogen chloride, and phosphoric acid. For example, the pH controller may be lithium hydroxide. In an embodiment, the pH controller may control the slurry composition SC so that the slurry composition SC has a pH selected from a range of about 2 to about 9. In order to control the pH of the slurry composition SC to a desired value, the pH controller consisting of an acid solution and/or an alkaline solution may be used in an appropriate amount. In the slurry composition SC, the pH controller may be included in an amount necessary to control the slurry composition SC to have a desired pH and is not particularly limited.

In example embodiments, the slurry composition SC may further include a corrosion inhibitor. The corrosion inhibitor may be selectively attached to the surface of a metal included in the metal film, which is a polishing target film, and may effectively suppress excessive corrosion of the metal film while maintaining a good polishing rate of the metal film. The corrosion inhibitor may be at least one selected from the group consisting of, for example, triazole and derivatives thereof and benzene triazole and derivatives thereof.

When the corrosion inhibitor is included in the slurry composition SC, the content of the corrosion inhibitor may be included in an amount of about 0.001 wt % to about 1 wt %, for example, about 0.001 wt % to about 0.5 wt %, based on the total amount of the slurry composition SC.

In example embodiments, the slurry composition SC may further include a biocide. The biocide may prevent the slurry composition SC or the metal film, which is the polishing target film to which the slurry composition SC is applied, from being contaminated with microorganisms. The biocide may be at least one selected from the group consisting of, for example, organotin compounds, salicylanilide, mercaptan, quaternary ammonium compounds, hydrogen peroxide, sodium chloride, and sodium hypochlorite.

When the slurry composition SC includes the biocide, the content of the biocide may be in a range from about 0.001 wt % to about 10 wt % based on the total amount of the slurry composition SC. In example embodiments, the content of the biocide may be in a range from about 0.001 wt % to about 5 wt %, from about 0.001 wt % to about 3 wt %, or from about 0.001 wt % to about 1 wt %.

Water included in the slurry composition CS may be deionized water. The content of the water included in the slurry composition CS is not particularly limited, and may be included as a remainder together with the main components including the abrasive particles, the inhibitor including the chalcogen group, the oxidizing agent, the nonionic compound including the hydrophilic functional group, and the pH controller in the slurry composition CS.

The slurry composition according to the comparative example has a problem in that it is difficult to selectively adsorb an inhibitor on a metal film including Mo and an insulating film including an oxide film and/or a nitride film. Therefore, there is a limit to selectively lowering the polishing rate of the non-polishing target film while maintaining the polishing rate of the metal film, which is the polishing target film.

On the other hand, the slurry composition SC of the present disclosure may suppress the polishing rate of the non-polishing target film while maintaining the polishing rate of the polishing target film in the target structure by selectively adsorbing the compound including the cystine only on the non-polishing target film. Therefore, the slurry composition SC of the present disclosure has the effect of selectively polishing the polishing target film.

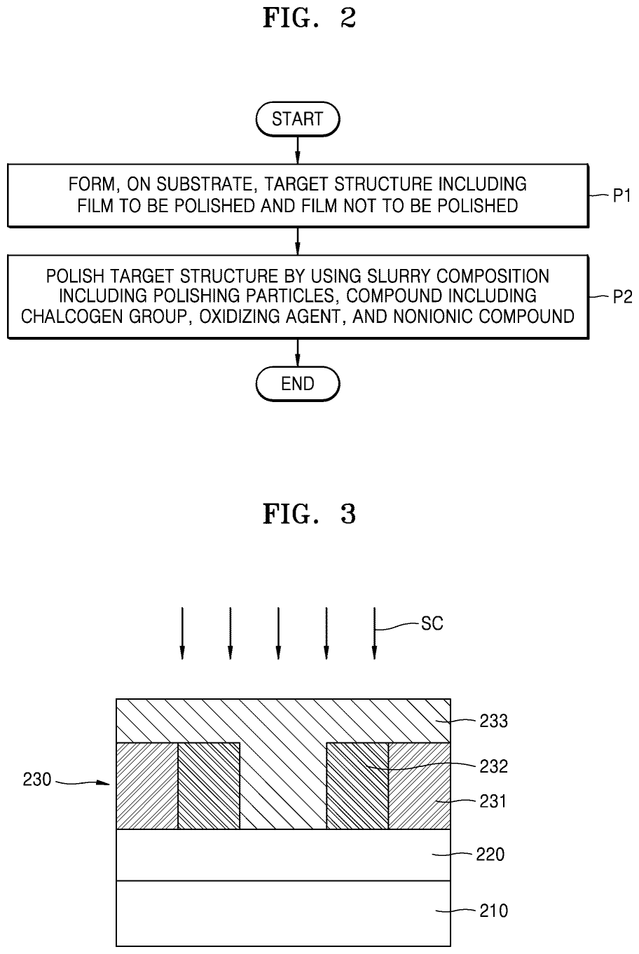

FIG. 2 is a flowchart for explaining a polishing process according to example embodiments.

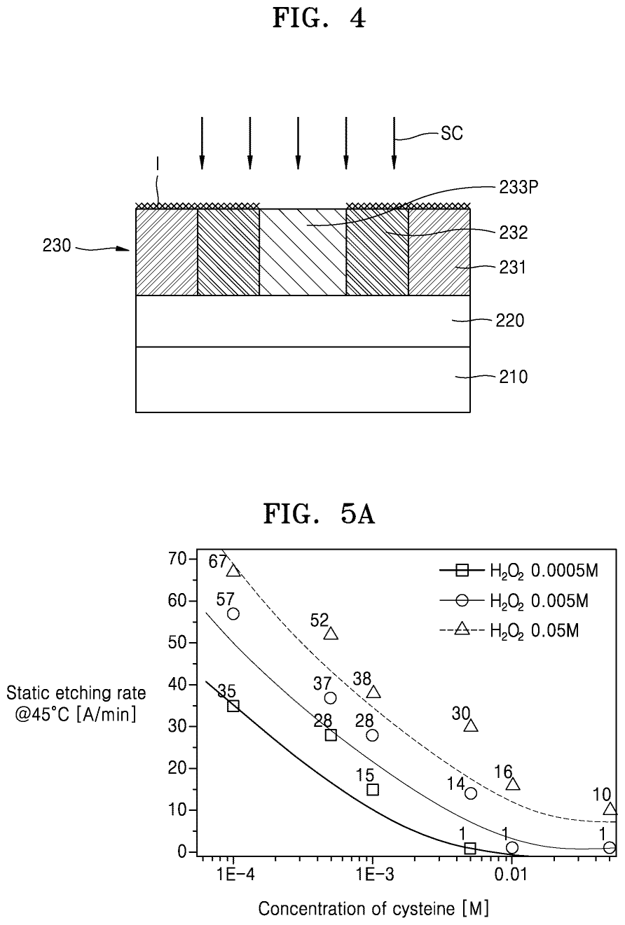

FIG. 3 and FIG. 4 are cross-sectional views for explaining a process sequence of a method of manufacturing an integrated circuit device according to example embodiments.

Referring to FIGS. 2 and 3, in process P1, a lower structure 220 may be formed on a substrate 210, and a target structure 230 including a polishing target film 233 and a first non-polishing target film 231 and a second non-polishing target film 232 may be formed on the lower structure 220. The polishing target film 233 and the first non-polishing target film 231 and the second non-polishing target film 232 are formed on the lower structure 220, and the polishing target film 233 may be formed to cover the first non-polishing target film 231 and the second non-polishing target film 232.

In example embodiments, the substrate 210 may include a semiconductor, such as Si or Ge, or a compound semiconductor such as SiGe, SiC, GaAs, InAs, or InP. The substrate 210 may include a conductive region (not shown). The conductive region may include a well doped with an impurity, a structure doped with an impurity, or a conductive layer.

In example embodiments, the lower structure 220 may include an insulating film including a silicon oxide film, a silicon nitride film, or a combination thereof. In some other embodiments, the lower structure 220 may include various conductive regions, such as a wiring layer, a contact plug, a transistor, and the like, and insulating patterns that insulate the wiring layer, the contact plug, and the transistor from each other.

In example embodiments, the polishing target film 233 may be a metal film. The metal film may include Mo, W, or a combination thereof. The non-polishing target films may include the first non-polishing target film 231 and the second non-polishing target film 232, each of which may be an insulating film. For example, the first non-polishing target film 231 may include silicon oxide SiO₂, and the second non-polishing target film 232 may include silicon nitride (Si₃N₄), but the present disclosure is not limited thereto.

Referring to FIGS. 2 and 4, in process P2, the polishing target film 233 may be polished by a CMP process using a slurry composition SC according to the technical idea of the present disclosure. As a result, the thickness of the polishing target film 233 covering the first non-polishing target film 231 and the second non-polishing target film 232 may be reduced, and a flattened film 233P may be obtained. The detailed composition of the slurry composition SC is as described above. For example, the slurry composition SC may include polishing particles, an inhibitor including a chalcogen group, an oxidizing agent, and a nonionic compound including a hydrophilic functional group.

In example embodiments, as the polishing target film 233 is polished by the CMP process, upper surfaces of the first non-polishing target film 231 and the second non-polishing target film 232 may be exposed.

In example embodiments, the inhibitor I of the slurry composition SC may be selectively adsorbed onto the surfaces of the first non-polishing target film 231 and the second non-polishing target film 232. The inhibitor I of the slurry composition SC may not be adsorbed on the surface of the polishing target film 233. At this time, the inhibitor I may include cystine formed by the reaction of cysteine and an oxidizing agent.

Due to the hydrophilic nature of the cystine, the cystine has a low affinity for Mo, so the inhibitor I may not be adsorbed on the surface of the polishing target film 233. On the other hand, a hydrogen bond is formed between the disulfide bond of the cystine and the first non-polishing target film 231 and the second non-polishing target film 232, and thus, the inhibitor I may be selectively adsorbed on the surfaces of the first non-polishing target film 231 and the second non-polishing target film 232.

The method of manufacturing an integrated circuit device of the present disclosure may selectively adsorb an inhibitor I including cystine only on the first non-polishing target film 231 and the second non-polishing target film 232. Accordingly, in the CMP process using the slurry composition SC, the polishing rate for the polishing target film 233 may be greater than the polishing rate for the first non-polishing target film 231 and the second non-polishing target film 232. Therefore, there is an effect of selectively polishing the polishing target film 233. Therefore, the productivity of the integrated circuit device manufacturing process using the CMP process using the slurry composition SC may be improved, and an integrated circuit device with improved reliability may be provided.

In another embodiment, the inhibitor I may include a nonionic compound including cystine and a hydrophilic functional group. The detailed composition of the nonionic compound including a hydrophilic functional group is as described above. For example, the nonionic compound including a hydrophilic functional group may include sorbitol, 1,3-propanediol, N,N-dimethyl acetamide, or a combination thereof.

In example embodiments, a nonionic compound including a hydrophilic functional group may be selectively adsorbed onto the surfaces of the first non-polishing target film 231 and the second non-polishing target film 232 by combining with the cystine. As the inhibitor I formed by combining the cystine and the nonionic compound including the hydrophilic functional group is selectively adsorbed onto the surfaces of the first non-polishing target film 231 and the second non-polishing target film 232, the frictional force between the first non-polishing target film 231 and the second non-polishing target film 232 is reduced, and thus, the polishing rate of the first non-polishing target film 231 and the second non-polishing target film 232 may be suppressed. Accordingly, in a CMP process using the slurry composition SC, the polishing rate for the polishing target film 233 may be greater than that for the first and second non-polishing target films 231 and 232. Therefore, there is an effect that the slurry composition SC may selectively polish the polishing target film 233. Therefore, the productivity of the integrated circuit device manufacturing process using the CMP process using the slurry composition may be improved, and an integrated circuit device with improved reliability may be provided.

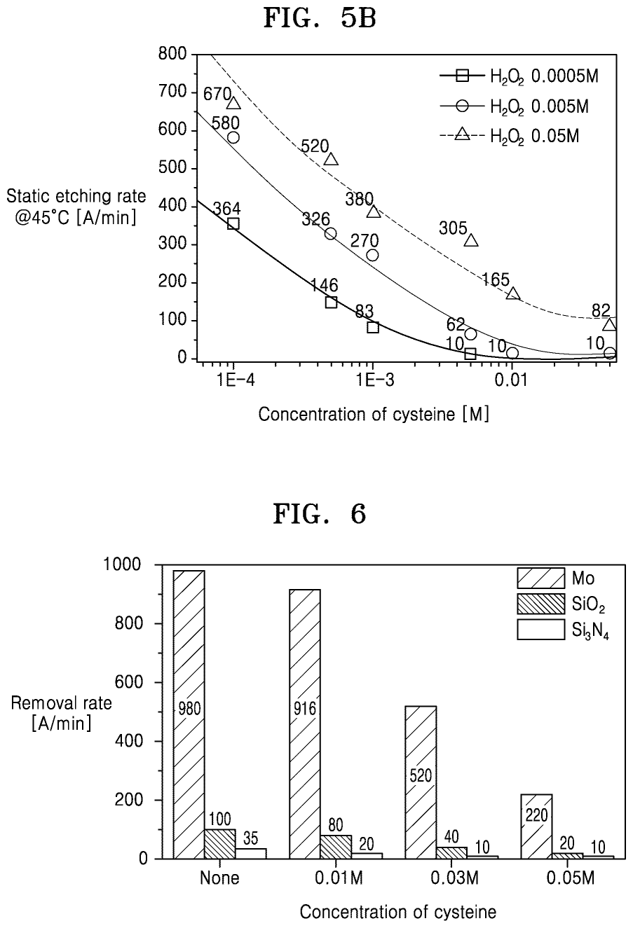

FIGS. 5A and 5B are graphs showing the results of a polishing process using a slurry composition according to embodiments.

FIGS. 5A and 5B are graphs showing changes in the static etch rate and removal rate of the polishing target film (e.g., a metal film including Mo) according to changes in the concentration of cysteine and the concentration of hydrogen peroxide.

In example embodiments, the slurry composition may include polishing particles, an inhibitor including a chalcogen group, and an oxidizing agent. For example, the polishing particles may include 1.0 wt % of silica having a primary particle size of 30 nm and a secondary particle size of 70 nm, the oxidizing agent may include hydrogen peroxide, and the inhibitor including the chalcogen group may include cysteine.

Referring to FIGS. 5A and 5B, it may be confirmed that as the concentration of cysteine increases, the static etching rate and the polishing rate of the polishing target film decrease. In addition, it may be confirmed that as the concentration of hydrogen peroxide increases, the static etching rate and the polishing rate of the polishing target film increase.

FIG. 6 is a graph showing the results of a polishing process using a slurry composition SC according to embodiments.

FIG. 6 is a graph showing the change in the polishing rate of a polishing target film (e.g., a metal film including Mo) and a non-polishing target film (e.g., an insulating film including silicon oxide or silicon nitride) according to the change in the concentration of cysteine.

In example embodiments, the slurry composition may include abrasive particles, an inhibitor including a chalcogen group, and an oxidizer. For example, the abrasive particles may include 1.0 wt % of silica having a primary particle size of 30 nm and a secondary particle size of 70 nm, the oxidizing agent may include 0.1 M hydrogen peroxide, and the inhibitor including a chalcogen group may include cysteine. At this time, the pH of the polishing process may be 2.0.

Referring to FIG. 6, it may be confirmed that as the concentration of cysteine increases, the polishing rate of the polishing target film and the non-polishing target film decreases. For example, when the slurry composition does not include cysteine, the polishing rate of the metal film including Mo is 980 A/min, the polishing rate of the silicon oxide film is 100 A/min, and the polishing rate of the silicon nitride film is 35 A/min. In addition, when the slurry composition includes cysteine at a concentration of 0.01 M, the polishing rate of the metal film including Mo is 916 A/min, the polishing rate of the silicon oxide film is 80 A/min, and the polishing rate of the silicon nitride film is 20 A/min. When the slurry composition includes cysteine, it may be confirmed that the amount of polishing rate reduction of the silicon oxide film and the amount of polishing rate reduction of the silicon nitride film are large compared to the amount of polishing rate reduction of the metal film including Mo.

When the slurry composition includes the cysteine, as described above, it may be confirmed that the polishing rate of the polishing target film is maintained while the polishing rate of the non-polishing target film is suppressed as the cysteine is selectively adsorbed to the surface of the non-polishing target film. Therefore, the slurry composition of the present disclosure may selectively polish the polishing target film.

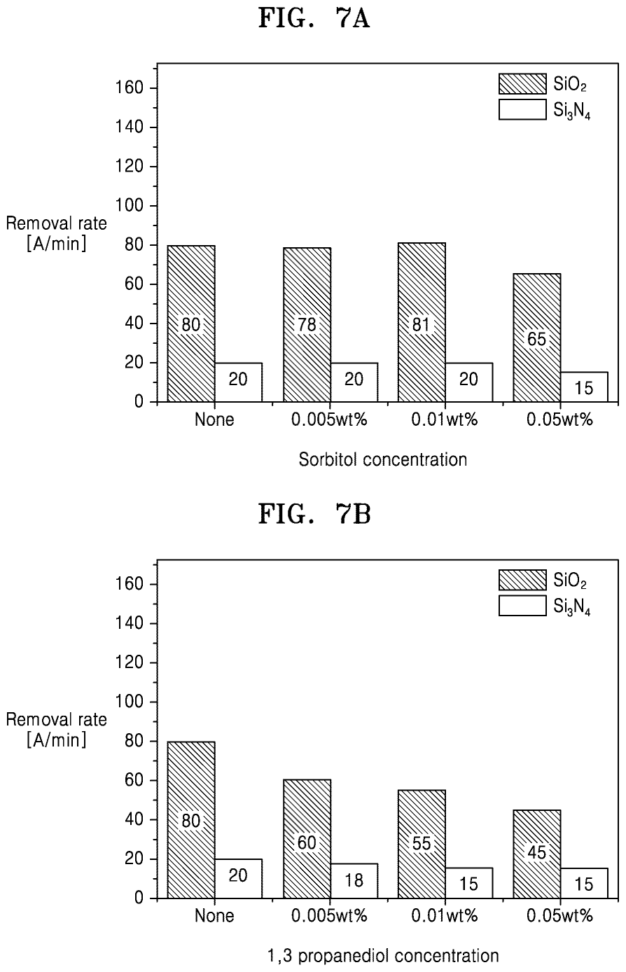

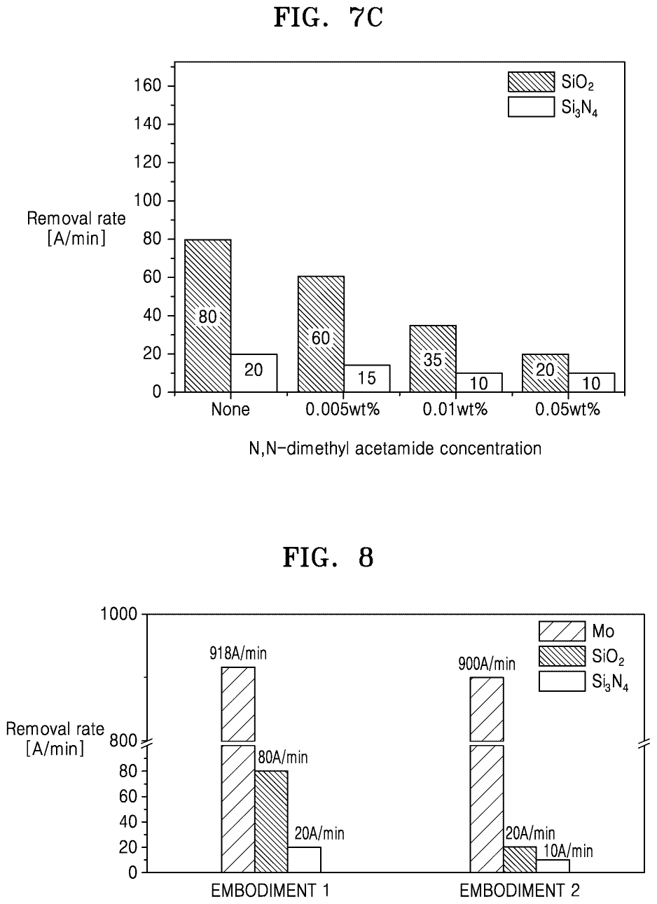

FIGS. 7A to 7C are graphs showing results of a polishing process using a slurry composition according to embodiments.

FIGS. 7A to 7C are graphs showing changes in polishing rates of silicon oxide films and silicon nitride films according to changes in the content of a nonionic compound including a hydrophilic functional group.

In example embodiments, the slurry composition may include polishing particles, an inhibitor including a chalcogen group, an oxidizing agent, and a nonionic compound including a hydrophilic functional group. For example, the polishing particles may include 1.0 wt % of silica having a primary particle size of 30 nm and a secondary particle size of 70 nm, the oxidizing agent may include a concentration of 0.1 M hydrogen peroxide, and the inhibitor including a chalcogen group may include a concentration of 0.01 M cysteine. At this time, the pH of the polishing process may be 2.0.

Referring to FIG. 7A, the nonionic compound including the hydrophilic functional group may include sorbitol. It may be confirmed that as the content of sorbitol increases, the polishing rate of the silicon oxide film and the silicon nitride film decreases. For example, when the slurry composition does not include sorbitol, the polishing rate of the silicon oxide film is 80 A/min, and the polishing rate of the silicon nitride film is 20 A/min. On the other hand, when the slurry composition includes 0.05 wt % of sorbitol based on the total weight of the slurry composition, the polishing rate of the silicon oxide film is 65 A/min, and the polishing rate of the silicon nitride film is 15 A/min. As a complex formed by combining the cystine and the sorbitol is selectively adsorbed to surfaces of the silicon oxide film and the silicon nitride film, the frictional force of the silicon oxide film and the silicon nitride film decreases, thereby suppressing the polishing rate of the silicon oxide film and the silicon nitride film.

Referring to FIG. 7B, the nonionic compound including the hydrophilic functional group may include 1,3-propanediol. It may be confirmed that as the content of 1,3-propanediol increases, the polishing rate of the silicon oxide film and the silicon nitride film decreases. For example, when the slurry composition does not include 1,3-propanediol, the polishing rate of the silicon oxide film is 80 A/min, and the polishing rate of the silicon nitride film is 20 A/min. On the other hand, when the slurry composition includes 0.05 wt % of 1,3-propanediol based on the total weight of the slurry composition, the polishing rate of the silicon oxide film is 45 A/min, and the polishing rate of the silicon nitride film is 15 A/min. As the complex formed by combining the cystine and the 1,3-propanediol is selectively adsorbed on the surfaces of the silicon oxide film and the silicon nitride film, the frictional force of the silicon oxide film and the silicon nitride film decreases, thereby suppressing the polishing rate of the silicon oxide film and the silicon nitride film.

Referring to FIG. 7C, the nonionic compound including the hydrophilic functional group may include N,N-dimethyl acetamide. It may be confirmed that as the content of N,N-dimethyl acetamide increases, the polishing rate of the silicon oxide film and the silicon nitride film decreases. For example, when the slurry composition does not include N,N-dimethyl acetamide, the polishing rate of the silicon oxide film is 80 A/min, and the polishing rate of the silicon nitride film is 20 A/min. On the other hand, when the slurry composition includes 0.05 wt % of N,N-dimethyl acetamide based on the total weight of the slurry composition, the polishing rate of the silicon oxide film is 20 A/min, and the polishing rate of the silicon nitride film is 10 A/min. As the complex formed by combining the cystine and the N,N-dimethyl acetamide is selectively adsorbed on the surfaces of the silicon oxide film and the silicon nitride film, the frictional force of the silicon oxide film and the silicon nitride film is reduced, and thus, the polishing rate of the silicon oxide film and the silicon nitride film may be suppressed.

Referring to FIGS. 7A to 7C, it may be confirmed that the polishing rate of the silicon oxide film and the silicon nitride film is suppressed as the slurry composition includes a nonionic compound including a hydrophilic functional group. In particular, when N,N-dimethyl acetamide is included, the polishing rate of the silicon oxide film and the silicon nitride film may be significantly reduced.

FIG. 8 is a graph showing the results of a polishing process using a slurry composition according to embodiments.

FIG. 8 is a graph showing the change in polishing rate of a polishing target film (e.g., a metal film including Mo) and a non-polishing target film (e.g., an insulating film including silicon oxide or silicon nitride) depending on whether the slurry composition of the present disclosure includes N,N-dimethyl acetamide. At this time, Embodiment 1 may not include N,N-dimethyl acetamide, and Embodiment 2 may include N,N-dimethyl acetamide.

In example embodiments, the slurry composition may include polishing particles, an inhibitor including a chalcogen group, an oxidizing agent, and a nonionic compound including a hydrophilic functional group. For example, the polishing particles may include 1.0 wt % of silica having a primary particle size of 30 nm and a secondary particle size of 70 nm, the oxidizing agent may include 0.1 M hydrogen peroxide, the inhibitor including the chalcogen group may include 0.01 M cysteine, and the nonionic compound including the hydrophilic functional group may include 0.05 wt % of N,N-dimethyl acetamide based on the total weight of the slurry composition. At this time, the pH of the polishing process may be 2.0.

In the case of Embodiment 1, the polishing rate of the metal film including Mo is 918 A/min, the polishing rate of the silicon oxide film is 80 A/min, and the polishing rate of the silicon nitride film is 20 A/min. In Embodiment 2, the polishing rate of the metal film including Mo is 900 A/min, the polishing rate of the silicon oxide film is 20 A/min, and the polishing rate of the silicon nitride film is 10 A/min. When the slurry composition includes the N,N-dimethyl acetamide, it may be confirmed that the reduction in the polishing rate of the silicon oxide film and the reduction in the polishing rate of the silicon nitride film are greater than the reduction in the polishing rate of the metal film including Mo.

While the present disclosure has been particularly shown and described with reference to embodiments thereof, it will be understood that various changes in form and details may be made therein without departing from the spirit and scope of the following claims.

What is claimed is:

1. A slurry composition used for polishing a target structure including a film to be polished and a film not to be polished, the slurry composition comprising:
polishing particles;
an inhibitor comprising a chalcogen group; and
an oxidizing agent,
wherein the inhibitor reacts with the oxidizing agent to form a dichalcogenide bond and is adsorbed onto the non-polishing target film.

2. The slurry composition of claim 1, wherein:
the inhibitor comprising the chalcogen group comprises cysteine,
the oxidizing agent comprises hydrogen peroxide, and
the cysteine reacts with the hydrogen peroxide to form cystine comprising a disulfide bond.

3. The slurry composition of claim 2, wherein the cystine is selectively adsorbed to a surface of the film not to be polished in the target structure.

4. The slurry composition of claim 1, further comprising a nonionic compound comprising a hydrophilic functional group.

5. The slurry composition of claim 4, wherein the nonionic compound comprises sorbitol, 1,3-propanediol, N,N-dimethyl acetamide, or a combination thereof.

6. The slurry composition of claim 4, wherein a content of the nonionic compound is in a range from about 0.001 wt % to about 10 wt %, based on the total weight of the slurry composition.

7. The slurry composition of claim 1, wherein a content of the inhibitor is in a range from about 0.001 wt % to about 10 wt %, based on the total weight of the slurry composition.

8. The slurry composition of claim 1, wherein:
the film to be polished comprises molybdenum (Mo), and
the film not to be polished comprises silicon nitride, silicon oxide, or a combination thereof.

9. The slurry composition of claim 1, wherein a polishing rate of the slurry composition with respect to the film to be polished is greater than a polishing rate of the slurry composition with respect to the film not to be polished.

10. A slurry composition that selectively polishes a polishing target film in a target structure, the slurry composition comprising:
polishing particles comprising silica;
an oxidizing agent;
a compound comprising a chalcogen group; and
a nonionic compound comprising a hydrophilic functional group.

11. The slurry composition of claim 10, wherein:
the compound comprising the chalcogen group comprises cysteine,
the oxidizing agent comprises hydrogen peroxide, and
the cysteine reacts with the hydrogen peroxide to form cystine comprising a disulfide bond.

12. The slurry composition of claim 11, wherein a content of the silica is in a range from about 0.01 wt % to about 20 wt %, based on the total weight of the slurry composition.

13. The slurry composition of claim 12, wherein the compound comprising the chalcogen group comprises sulfur(S), selenium (Se), tellurium (Te), or a combination thereof.

14. The slurry composition of claim 13, wherein the nonionic compound comprising a hydrophilic functional group comprises sorbitol, 1,3-propanediol, N,N-dimethyl acetamide, or a combination thereof.

15. The slurry composition of claim 10, wherein the nonionic compound including a hydrophilic functional group comprises N,N-dimethyl acetamide.

16. The slurry composition of claim 15, wherein a content of the nonionic compound is in a range from about 0.001 wt % to about 10 wt %, based on the total weight of the slurry composition.

17. The slurry composition of claim 15, wherein:
a content of the compound comprising the chalcogen group is in a range from about 0.001 wt % to about 10 wt %, based on the total weight of the slurry composition, and
a content of the nonionic compound is in a range from about 0.001 wt % to about 10 wt %, based on the total weight of the slurry composition.

18. The slurry composition of claim 10, wherein the slurry composition has a pH in a range of 2 to 9.

19. A slurry composition used for polishing a target structure comprising a film to be polished comprising molybdenum (Mo) and a film not to be polished comprising silicon nitride, silicon oxide or a combination thereof, the slurry composition comprising:
polishing particles;
an oxidizing agent;
an inhibitor comprising cysteine; and
a nonionic compound including a hydrophilic functional group,
wherein the cysteine reacts with the oxidizing agent to form cystine comprising a disulfide bond, and the cystine selectively adsorbs onto a surface of the film not to be polished in the target structure.

20. The slurry composition of claim 19, wherein the nonionic compound comprises sorbitol, 1,3-propanediol, N,N-dimethyl acetamide, or a combination thereof.
